(19) United States
(12) Patent Application Publication
(10) Pub. No.: US 2025/0157799 A1
(43) Pub. Date: May 15, 2025

(54) MONITORING METHOD AND PLASMA PROCESSING APPARATUS

(71) Applicant: Tokyo Electron Limited, Tokyo (JP)

(72) Inventors: Mohd Fairuz BIN BUDIMAN, Miyagi (JP); Shinya MORIKITA, Miyagi (JP)

(73) Assignee: Tokyo Electron Limited, Tokyo (JP)

(21) Appl. No.: 19/021,566

(22) Filed: Jan. 15, 2025

Related U.S. Application Data
(63) Continuation of application No. PCT/JP2023/026289, filed on Jul. 18, 2023.

(30) Foreign Application Priority Data
Jul. 22, 2022 (JP) 2022-117158

(51) Int. Cl. H01J 37/32

(52) U.S. Cl. CPC H01J 37/32935; H01J 37/32724; H01J 2237/24578; H01J 2237/24585

(57) ABSTRACT

A monitoring method includes determining first power provided to heaters each located in a corresponding zone of a plurality of zones in a substrate support in a chamber. The first power is provided when plasma is generated in the chamber and each zone is controlled to be at a constant temperature with the corresponding heater in the zone. The monitoring method further includes determining a heat flux from the plasma to each zone. The heat flux from the plasma to each zone is obtained by dividing a difference between second power and the first power provided to the corresponding heater in the zone by an area of the zone. The second power to the corresponding heater in the zone is provided when no plasma is generated in the chamber and the zone is controlled to be at the constant temperature with the corresponding heater in the zone.

### CROSS-REFERENCE TO RELATED APPLICATIONS

This application is a Continuation of PCT International Application No. PCT/JP2023/026289, filed on Jul. 18, 2023, which claims priority under 35 U.S.C. § 119 (a) to Japanese Patent Application No. JP2022-117158, filed in Japan on Jul. 22, 2022, all of which are hereby expressly incorporated by reference into the present application.

### FIELD

One or more embodiments of the present application relate to a monitoring method and a plasma processing apparatus.

### BACKGROUND

Plasma processing is performed on substrates using a plasma processing apparatus. The plasma processing apparatus includes a chamber and a substrate support. The substrate support is located in the chamber and supports a substrate placed on the substrate support. The substrate support may include heaters each located in the respective zones in the substrate support. The temperatures of the respective zones of the substrate support are individually adjusted with the heaters to adjust the temperatures of multiple areas of the substrate individually. Patent Literature 1 describes such a plasma processing apparatus.

### CITATION LIST

### Patent Literature

Patent Literature 1: Japanese Unexamined Patent Application Publication No. 2016-001688

### BRIEF SUMMARY

### Technical Problem

One or more aspects of the disclosure are directed to a technique for monitoring the conditions of plasma.

### Solution to Problem

A monitoring method according to one or more embodiments of the present application includes determining first power provided to heaters each located in a corresponding zone of a plurality of zones in a substrate support in a plasma processing apparatus. The substrate support is located in a chamber in the plasma processing apparatus. The first power is provided when plasma is generated in the chamber and each of the plurality of zones is controlled to be at a constant temperature with the corresponding heater in the zone. The monitoring method further includes determining a heat flux from the plasma to each of the plurality of zones. The heat flux from the plasma to each of the plurality of zones is obtained by dividing a difference between second power and the first power provided to the corresponding heater in the zone by an area of the zone. The second power to the corresponding heater in the zone is provided when no plasma is generated in the chamber and the zone is controlled to be at the constant temperature with the corresponding heater in the zone.

### Advantageous Effects

The technique according to one or more embodiments of the present application can monitor the conditions of plasma.

### BRIEF DESCRIPTION OF DRAWINGS

FIG. 1 is a flowchart of a monitoring method according to one or more embodiments of the present application.

FIG. 2 is a schematic diagram of a plasma processing apparatus according to one or more embodiments of the present application.

FIG. 3 is an enlarged cross-sectional view of a substrate support in the plasma processing apparatus according to one or more embodiments of the present application.

FIG. 4 is a diagram of multiple zones and multiple heaters in the plasma processing apparatus according to one or more embodiments of the present application in an example layout.

FIG. 5 is a diagram of a measurement system for a self-bias voltage in the plasma processing apparatus according to one or more embodiments of the present application.

### DETAILED DESCRIPTION

One or more embodiments of the present application will now be described.

A monitoring method according to one or more embodiments of the present application includes determining first power provided to heaters each located in a corresponding zone of a plurality of zones in a substrate support in a plasma processing apparatus. The substrate support is located in a chamber in the plasma processing apparatus. The first power is provided when plasma is generated in the chamber and each of the plurality of zones is controlled to be at a constant temperature with the corresponding heater in the zone. The monitoring method further includes determining a heat flux from the plasma to each of the plurality of zones. The heat flux from the plasma to each of the plurality of zones is obtained by dividing a difference between second power and the first power provided to the corresponding heater in the zone by an area of the zone. The second power to the corresponding heater in the zone is provided when no plasma is generated in the chamber and the zone is controlled to be at the constant temperature with the corresponding heater in the zone.

The difference between the second power and the first power corresponds to a heat input from the plasma. The heat input from the plasma to each zone can be divided by the area of the corresponding zone to determine the heat flux to the zone. The heat flux to each zone reflects the density of the plasma above the zone. The technique according to the above allows monitoring the conditions of plasma above each zone.

A monitoring method according to one or more embodiments of the present application may further include determining a time-integrated value of the heat flux from the plasma to each of the plurality of zones or a time-integrated value of a heat input from the plasma to each of the plurality of zones. The monitoring method may further include controlling plasma processing with the plasma based on the time-integrated value of the heat flux from the plasma to each of the plurality of zones or based on the time-integrated value of the heat input from the plasma to each of the plurality of zones. In one or more embodiments of the present application, controlling the plasma processing may include performing different plasma processing in the chamber when the time-integrated value of the heat flux or the time-integrated value of the heat input reaches a predetermined value.

A monitoring method according to one or more embodiments of the present application may further include determining a thickness of a plasma sheath above each of the plurality of zones based on the heat flux from the plasma to the zone and a self-bias voltage in the substrate support. A monitoring method according to one or more embodiments of the present application may further include determining a direction in which ions from the plasma travel in a space above each of the plurality of zones based on the thickness of the plasma sheath above the zone.

A plasma processing apparatus according to another exemplary embodiment includes a chamber, a plasma generator, a substrate support, a heater controller, and a controller. The plasma generator generates plasma in the chamber. The substrate support is located in the chamber. The substrate support includes heaters each located in a corresponding zone of a plurality of zones in the substrate support. The heater controller provides power to the heaters in the plurality of zones. The controller determines first power provided from the heater controller to the corresponding heater in each of the plurality of zones when the plasma is generated in the chamber and each of the plurality of zones is controlled to be at a constant temperature with the corresponding heater in the zone. The controller determines a heat flux from the plasma to each of the plurality of zones by dividing a difference between second power and the first power provided to the corresponding heater in the zone by an area of the zone. The second power to the corresponding heater in each of the plurality of zones is provided when no plasma is generated in the chamber and the zone is controlled to be at the constant temperature with the corresponding heater in the zone.

In one or more embodiments of the present application, the controller may determine a time-integrated value of the heat flux from the plasma to each of the plurality of zones or a time-integrated value of a heat input from the plasma to each of the plurality of zones. The controller may control plasma processing with the plasma based on the time-integrated value of the heat flux from the plasma to each of the plurality of zones or the time-integrated value of the heat input from the plasma to each of the plurality of zones. In one or more embodiments of the present application, the controller may perform different plasma processing in the chamber when the time-integrated value of the heat flux or the time-integrated value of the heat input reaches a predetermined value.

In one or more embodiments of the present application, the controller may determine a thickness of a plasma sheath above each of the plurality of zones based on the heat flux from the plasma to the zone and a self-bias voltage in the substrate support. In one or more embodiments of the present application, the controller may determine a direction in which ions from the plasma travel in a space above each of the plurality of zones based on the thickness of the plasma sheath above the zone.

One or more embodiments of the present application will now be described in detail with reference to the drawings. In the figures, like reference numerals denote like or corresponding components.

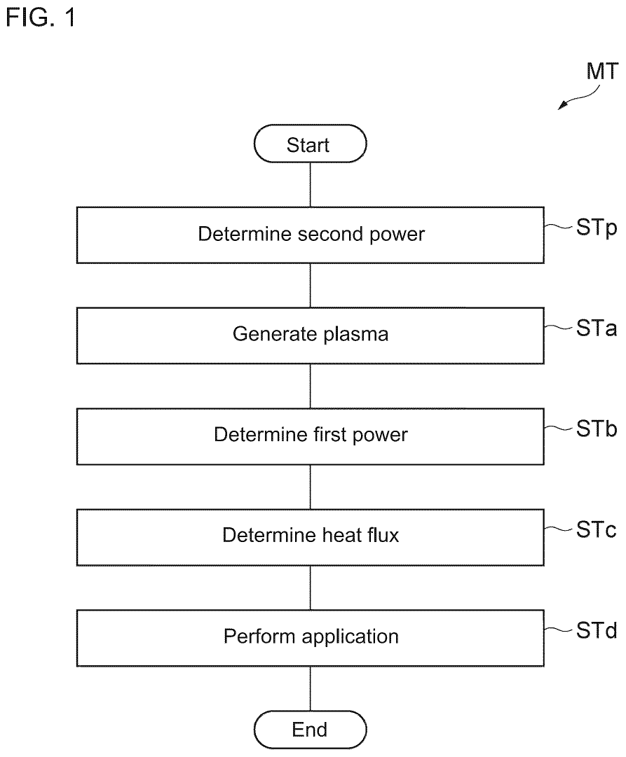

FIG. 1 is a flowchart of a monitoring method according to one or more embodiments of the present application. The monitoring method shown in FIG. 1 (hereafter referred to as a method MT) is implemented using a plasma processing apparatus.

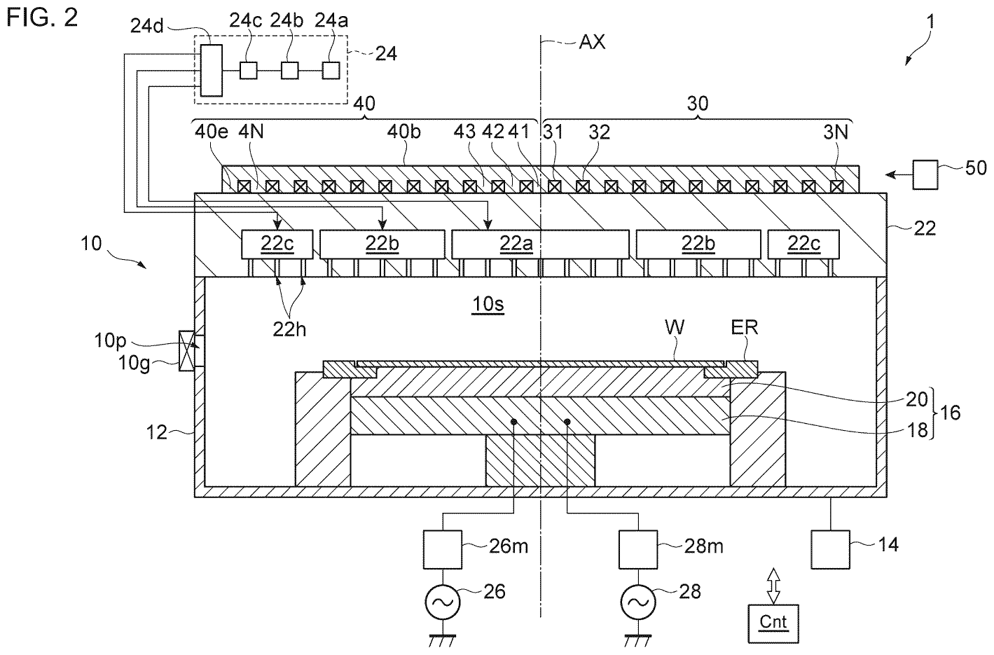

FIG. 2 is a schematic diagram of a plasma processing apparatus according to one or more embodiments of the present application. A plasma processing apparatus 1 shown in FIG. 2 may be used with the method MT. The plasma processing apparatus 1 is a capacitively coupled plasma processing apparatus. The plasma processing apparatus 1 includes a chamber 10.

The chamber 10 is substantially cylindrical and defines an internal space 10s. An axis AX shown in FIG. 2 is the central axis of the chamber 10 and the internal space 10s and extends vertically. The radial direction and the circumferential direction hereafter refer to the directions with respect to the axis AX.

The chamber 10 may include a chamber body 12. The chamber body 12 is substantially cylindrical. The chamber body 12 is formed from a metal such as aluminum and is grounded. The chamber body 12 has the internal space 10s. The internal space 10s is decompressible with an exhaust device 14.

The chamber 10 has a side wall having a port 10p. A substrate W is transferred between the inside and the outside of the chamber 10 through the port 10p. The port 10p is open and closed by a gate valve 10g. The gate valve 10g is on the side wall of the chamber 10.

The plasma processing apparatus 1 further includes a substrate support 16. The substrate support 16 is located in the chamber 10. The substrate support 16 supports a substrate W placed on the substrate support 16. The substrate support 16 has the central axis aligned with the axis AX.

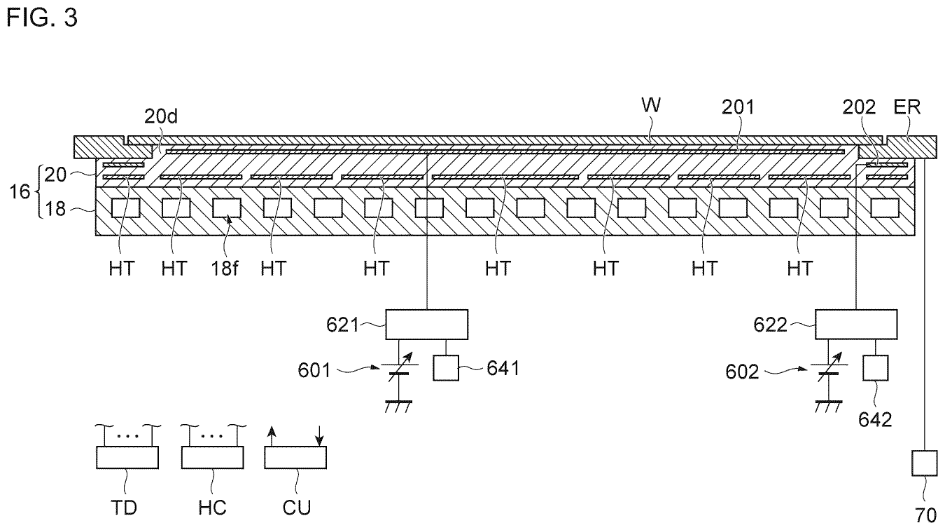

FIG. 3 will now be referred to in addition to FIG. 2. FIG. 3 is an enlarged cross-sectional view of a substrate support in the plasma processing apparatus according to one or more embodiments of the present application. In one or more embodiments of the present application, the substrate support 16 may include a base 18 and an electrostatic chuck (ESC) 20. The base 18 is substantially disk-shaped and is formed from a conductive material such as aluminum. The base 18 may define a channel 18f inside. The channel 18f receives a refrigerant from a chiller unit CU. The refrigerant fed from the chiller unit CU flows through the channel 18f and returns to the chiller unit CU.

The ESC 20 is located on the base 18. As shown in FIG. 3, the substrate W is placed on the ESC 20 with its center on the axis AX. The substrate W may have a diameter of, for example, 300 mm. The substrate support 16 may further support an edge ring ER placed on the substrate support 16. The substrate W is placed in an area on the ESC 20 surrounded by the edge ring ER.

The ESC 20 includes a dielectric portion 20d and electrodes 201 and 202. The dielectric portion 20d is formed from a dielectric such as aluminum nitride or aluminum oxide. The dielectric portion 20d is substantially disk-shaped. The dielectric portion 20d includes a substrate support area and an edge ring support area. The substrate support area receives the substrate W. The edge ring support area receives the edge ring ER. The edge ring support area extends circumferentially to surround the substrate support area.

The electrode 201 is a conductive film located in the substrate support area of the dielectric portion 20d. The electrode 201 is electrically coupled to a power supply 601. A direct current (DC) voltage is applied from the power supply 601 to the electrode 201 to generate an electrostatic attraction between the ESC 20 and the substrate W. The electrostatic attraction causes the ESC 20 to attract and hold the substrate W.

The electrode 202 is a conductive film located in the edge ring support area of the dielectric portion 20d. The electrode 202 is electrically coupled to a power supply 602. A DC voltage is applied from the power supply 602 to the electrode 202 to generate an electrostatic attraction between the ESC 20 and the edge ring ER. The electrostatic attraction causes the ESC 20 to attract and hold the edge ring ER. The electrode 202 may be a bipolar electrode serving as a bipolar ESC.

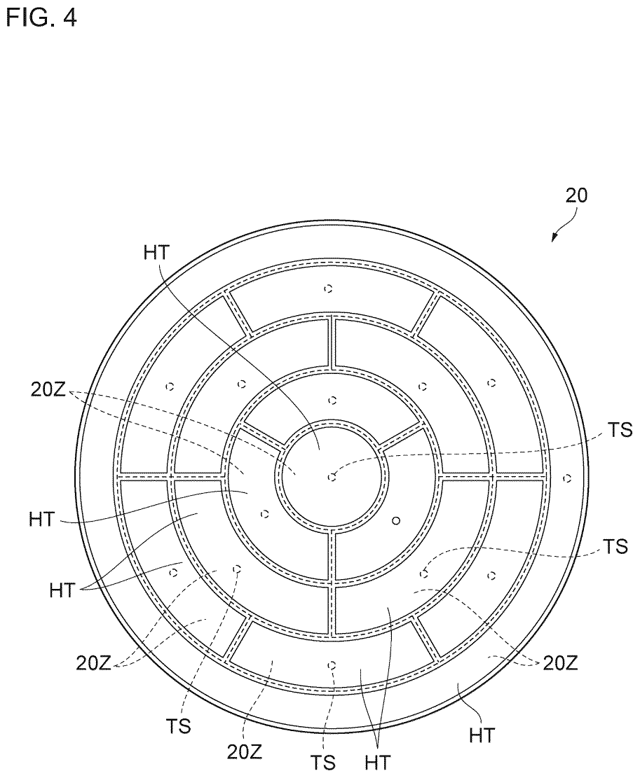

The substrate support 16 includes multiple zones 20Z. FIG. 4 will now be referred to, in addition to FIGS. 2 and 3. FIG. 4 is a diagram of multiple zones and multiple heaters in the plasma processing apparatus according to one or more embodiments of the present application in an example layout. In one or more embodiments of the present application, the zones 20Z are located in the ESC 20. The zones 20Z are defined on the plane orthogonal to the axis AX. As shown in FIG. 4, the ESC 20 may include multiple areas coaxial with one another, and each area may include one or more zones 20Z. The outermost zone 20Z in the radial direction (in the annular area at the outermost periphery) is located below the edge ring ER. In the example shown in FIG. 4, the annular area at the outermost periphery includes a single zone 20Z. However, the annular area at the outermost periphery may include multiple zones. In this case, the zones are defined in the circumferential direction in the annular area at the outermost periphery.

The substrate support 16 further includes multiple heaters HT. The heaters HT are located in the respective zones 20Z. Each heater HT is, for example, a resistance heating element. Each heater HT receives power from a heater controller HC individually and generates heat.

The substrate support 16 further includes multiple temperature sensors TS and a temperature meter TD. The temperature sensors TS output sensor values reflecting the temperatures of the zones 20Z to the temperature meter TD. The temperature meter TD determines the temperature measurement values of the respective zones 20Z based on the sensor values of the respective zones 20Z. The heater controller HC individually controls power to be provided to each zone 20Z to adjust the temperature of the zone 20Z to be at a constant temperature based on the temperature measurement value of the zone 20Z.

As shown in FIG. 2, the plasma processing apparatus 1 further includes an upper electrode 22. The upper electrode 22 is located above the substrate support 16. The upper electrode 22 closes a top opening of the chamber body 12. The upper electrode 22 also serves as a shower head. In one or more embodiments of the present application, the upper electrode 22 defines multiple gas-diffusion compartments 22a to 22c and multiple gas holes 22h. The upper electrode 22 may define two or more gas-diffusion compartments.

The gas-diffusion compartments 22a to 22c are separate from one another and coaxial with one another in the upper electrode 22. The gas-diffusion compartments 22a to 22c have the axis AX at the center. The gas-diffusion compartment 22a is a space circular as viewed in plan and intersecting with the axis AX. Each of the gas-diffusion compartments 22b and 22c is a substantially annular space. The gas-diffusion compartment 22b is located radially outside the gas-diffusion compartment 22a. The gas-diffusion compartment 22c is located radially outside the gas-diffusion compartment 22b. The gas holes 22h extend downward from the gas-diffusion compartments 22a to 22c and are open toward the internal space 10s.

The plasma processing apparatus 1 further includes a gas supply 24. The gas supply 24 supplies a process gas into the chamber 10. In one or more embodiments of the present application, the gas supply 24 can adjust the flow rate distribution of the process gas to be provided to the substrate W in the radial direction of the substrate W. In one or more embodiments of the present application, the gas supply 24 supplies the process gas into the chamber 10 through the shower head described above, and supplies the process gas individually to each of the gas-diffusion compartments 22a to 22c.

The gas supply 24 may include a gas source set 24a, a flow rate controller set 24b, a valve set 24c, and a flow splitter 24d. The gas source set 24a includes one or more gas sources. The gases from the gas sources form the process gas. The flow rate controller set 24b includes one or more flow controllers. The valve set 24c includes one or more open-close valves. Each gas source in the gas source set 24a is connected to the flow splitter 24d through the corresponding flow rate controller in the flow rate controller set 24b and the corresponding open-close valve in the valve set 24c. The flow splitter 24d distributes the supplied process gas to the multiple gas-diffusion compartments 22a to 22c. The flow splitter 24d can adjust the distribution ratio of the process gas to the gas-diffusion compartments 22a to 22c.

In the plasma processing apparatus 1, the process gas supplied to the gas-diffusion compartment 22a is then supplied to a central area of the substrate W through the gas holes 22h connecting with the gas-diffusion compartment 22a. The process gas supplied to the gas-diffusion compartment 22b is supplied to an edge area of the substrate W through the gas holes 22h connecting with the gas-diffusion compartment 22b. The process gas supplied to the gas-diffusion compartment 22c is supplied to an area radially outward from the edge of the substrate W through the gas holes 22h connecting with the gas-diffusion compartment 22c. The gas supply 24 can adjust the distribution ratio of the process gas to the gas-diffusion compartments 22a to 22c using the flow splitter 24d and thus can adjust the flow rate distribution of the process gas in the radial direction of the substrate W.

The plasma processing apparatus 1 further includes a radio-frequency (RF) power supply 26. The RF power supply 26 serves as the plasma generator in one or more embodiments of the present application. The RF power supply 26 is coupled to an RF electrode through a matcher 26m. The RF power supply 26 generates source RF power to be provided to the RF electrode. The RF electrode may be an electrode in the substrate support 16. In one or more embodiments of the present application, the RF electrode may be the base 18. The source RF power has a frequency suitable for generating plasma. The matcher 26m includes a matching circuit that matches the impedance of the load for the RF power supply 26 with the output impedance of the RF power supply 26. The RF power supply 26 may be coupled to the upper electrode 22. More specifically, the upper electrode 22 may be an RF electrode.

The plasma processing apparatus 1 may further include a bias power supply 28. The bias power supply 28 is electrically coupled to a bias electrode in the substrate support 16. The bias power supply 28 generates an electrical bias to be provided to the bias electrode. An electrical bias is provided to the bias electrode in the substrate support 16 to draw ions toward the substrate W. In one or more embodiments of the present application, the bias electrode may be the base 18. An electrical bias generated by the bias power supply 28 may be bias RF power. When the electrical bias is bias RF power, the bias power supply 28 is coupled to the bias electrode through the matcher 28m. The matcher 28m includes a matching circuit that matches the impedance of a load for the bias power supply 28 with the output impedance of the bias power supply 28. In some embodiments, an electrical bias generated by the bias power supply 28 may be a pulsed voltage generated intermittently or periodically. When the electrical bias is a pulsed voltage, the plasma processing apparatus 1 does not include the matcher 28m.

In the plasma processing apparatus 1, a process gas is supplied into the chamber 10 from the gas supply 24. The chamber 10 is decompressed with the exhaust device 14. The RF power supply 26 provides source RF power to the RF electrode. Plasma is thus generated from the process gas in the chamber 10. The substrate W is then processed with chemical species such as radicals or ions from the plasma. For example, a film on the substrate W is etched. The energy of the ions supplied to the substrate W is adjustable with an electrical bias from the bias power supply 28.

As shown in FIG. 2, the plasma processing apparatus 1 may further include multiple electromagnets 30. The electromagnets 30 are arranged on or in the ceiling (upper electrode 22) of the chamber 10. The electromagnets 30 include electromagnets 31 to 3N. Each electromagnet 30 includes a coil wound around the axis AX. The electromagnets 30 have different inner diameters and are coaxial with one another. Some of the electromagnets 30 are located above the substrate W. One or more of the electromagnets 30 may be located above an area outward from the edge of the substrate W.

The plasma processing apparatus 1 may further include a bobbin member 40. The bobbin member 40 may be formed from a magnetic material. The bobbin member 40 includes bobbins 41 to 4N. The coils in the electromagnets 31 to 3N are wound around the respective bobbins 41 to 4N. The bobbins 41 to 4N are coaxial with one another, and have the axis AX at the center. The bobbin 41 is a solid cylinder. The bobbins 42 to 4N are hollow cylinders and located radially outside the bobbin 41. The bobbin member 40 may further include a cylindrical portion 40e and a base portion 40b. The cylindrical portion 40e is concentric with the bobbins 41 to 4N and is located radially outside the bobbins 4N to surround the electromagnet 3N. The base portion 40b is substantially disk-shaped. The bobbins 41 to 4N and the cylindrical portion 40e are integral with the base portion 40b and extend downward from the base portion 40b.

The plasma processing apparatus 1 further includes a power supply 50. The power supply 50 individually supplies current to the coils in the electromagnets 30. The current fed from the power supply 50 to the coils in the electromagnets 30 is, for example, DC. The current to be supplied from the power supply 50 to the coils in the electromagnets 30 is individually controlled by a controller Cnt (described later).

Each electromagnet 30 forms a magnetic field axially symmetric to the axis AX in the chamber 10. The magnetic field formed by each electromagnet 30 forms a combined magnetic field in the chamber 10. This combined magnetic field is also axially symmetric to the axis AX. Controlling the current supplied to each electromagnet 30 allows adjustment of the magnetic field strength distribution in the radial direction with respect to the axis AX. The plasma processing apparatus 1 can thus adjust the plasma density distribution in the chamber in the radial direction of the substrate W.

In one or more embodiments of the present application, the plasma processing apparatus 1 may further include a first measurement system and a second measurement system. The first measurement system measures a self-bias voltage V_{dcW} of the substrate W. The first measurement system includes a relay box 621 and a measurement device 641. The second measurement system measures a self-bias voltage V_{dcE} of the edge ring ER. The second measurement system includes a relay box 622 and a measurement device 642. The relay box 621 may be a part of the measurement device 641. The relay box 622 may be a part of the measurement device 642.

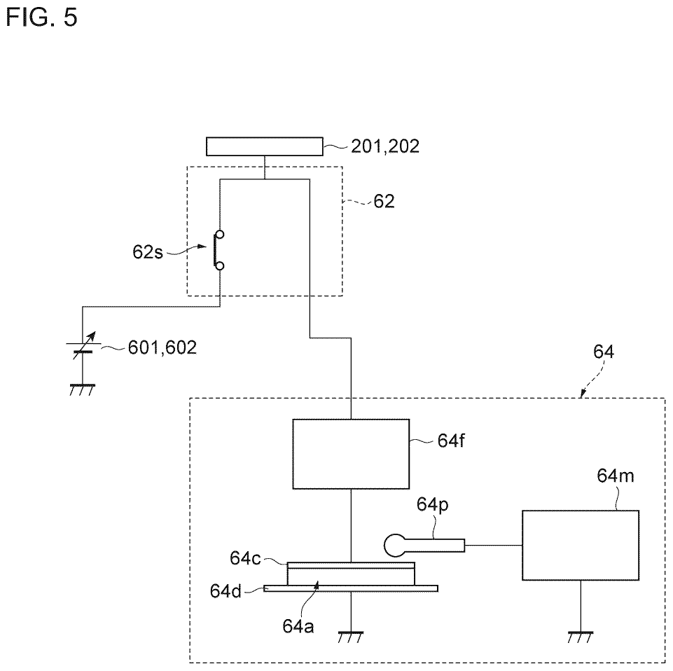

FIG. 5 will now be referred to. FIG. 5 is a diagram showing the measurement system for a self-bias voltage in the plasma processing apparatus according to one or more embodiments of the present application. The relay box 62 shown in FIG. 5 is used as the relay box 621 and the relay box 622. The measurement device 64 shown in FIG. 5 is used as the measurement device 641 and the measurement device 642.

The measurement device 64 includes a filter 64f, a capacitive member, a probe 64p, and a potential meter 64m. The filter 64f blocks RF power. The capacitive member includes, for example, an acrylic plate 64a between a copper disk 64c and a copper plate 64d. The copper disk 64c is coupled to the electrode (electrode 201 or 202) through the filter 64f and the relay box 62. The copper plate 64d is grounded. The potential meter 64m measures a potential of the copper disk 64c using a probe 64p located above the surface of the copper disk 64c without in contact with the copper disk 64c.

The relay box 621 switches the coupling of the electrode 201 between the power supply 601 and the capacitive member in the measurement device 641. The power supply 601 is coupled to the electrode 201 through a switch 62s in the relay box 621. When the switch 62s in the relay box 621 is in a closed state, a voltage from the power supply 601 is applied to the electrode 201. When the switch 62s in the relay box 621 is in an open state, the potential meter 64m in the measurement device 641 measures a floating voltage V₂₁ produced in the capacitive member in the measurement device 641.

The relay box 622 switches the coupling of the electrode 202 between the power supply 602 and the capacitive member in the measurement device 642. The power supply 602 is coupled to the electrode 202 through the switch 62s in the relay box 622. With the switch 62s in the relay box 622 in a closed state, a voltage from the power supply 602 is applied to the electrode 202. With the switch 62s in the relay box 622 in an open state, the potential meter 64m in the measurement device 642 measures a floating voltage V₂₂ that occurs in the capacitive member in the measurement device 642.

The controller Cnt determines a self-bias voltage V_{dcW} of the substrate W using Formula 1 below.

V_{dcW}=V₂₁×(C₂+C₃)/C₁₁+V₂₁ (1)

The controller Cnt determines a self-bias voltage V_{dcE} of the edge ring ER using Formula 2 below.

V_{dcE}=V₂₂×(C₂+C₃)/C₁₂+V₂₂ (2)

In the above formulas, Cu is the capacitance of the substrate support area of the ESC 20, and C₁₂ is the capacitance of the edge ring support area of the ESC 20. In the above formulas, C₂ is the capacitance determined by the structures of the copper disk 64c, the copper plate 64d, and the acrylic plate 64a, and C₃ is the capacitance determined by the structure of the filter 64f.

The plasma processing apparatus 1 further includes the controller Cnt. The controller Cnt is a computer including a processor, a storage, an input device, and a display, and controls the components of the plasma processing apparatus 1. More specifically, the controller Cnt executes a control program stored in the storage to control the components of the plasma processing apparatus 1 based on recipe data stored in the storage. In response to the control by the controller Cnt, a process specified by the recipe data is performed in the plasma processing apparatus 1. The method MT may be implemented by controlling the components of the plasma processing apparatus 1 with the controller Cnt. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

Referring back to FIG. 1, the method MT will now be described. The method MT includes steps STa to STc and step STp. In step STa, plasma is generated in the chamber 10. In step STa, the controller Cnt controls the gas supply 24 to supply the process gas into the chamber 10. In step STa, the controller Cnt also controls the exhaust device 14 to maintain the chamber 10 at a specified pressure. In step STa, the controller Cnt also controls the plasma generator to generate plasma from the process gas in the chamber. In one or more embodiments of the present application, the controller Cnt controls the RF power supply 26 to provide source RF power. In step STa, the heater controller HC individually controls power to be provided to the respective heaters HT to adjust the temperatures of the zones 20Z to a constant temperature Tc specified by the controller Cnt. The heater controller HC individually controls power to be provided to the heaters HT based on the temperatures of the respective zones 20Z measured by the temperature meter TD.

In step STb, first power P_{ON} provided from the heater controller HC to the heaters HT in the respective zones 20Z is determined. More specifically, first power P_{ON}[i] provided from the heater controller to a heater HT[i] in a zone 20Z[i] is determined. The symbol i herein refers to an index for each zone 20Z. The first power P_{ON}[i] can be determined by the controller Cnt. The first power P_{ON}[i] is provided to the heater HT[i] when plasma is generated in step STa and the zone 20Z[i] is controlled to be at the constant temperature Tc with the heater HT[i]. The first power P_{ON}[i] is calculated using Formula 3 below.

P_{ON}[i]=V_{ON}[i]²/R[i]×D[i]×c[i] (3)

In Formula 3, V_{ON}[i] is the average of AC voltages applied from the heater controller HC to the heater HT[i]. In Formula 3, R [i] is the resistance of the heater HT[i]. In Formula 3, D[i] is the ratio of the power provided from the heater controller HC to the heater HT[i] in step STa to the maximum power that can be provided from the heater controller HC to the heater HT[i]. In Formula 3, c[i] is a predefined coefficient for the zone 20Z[i].

In step STc, a heat flux Γ from the plasma generated in step STa to each zone 20Z is determined. More specifically, a heat flux Γ[i] from the plasma generated in step STa to the zone 20Z[i] is determined. The heat flux Γ[i] can be determined by the controller Cnt. The heat flux Γ[i] is calculated using Formula 4 below.

Γ[i]=(P_{OFF}[i]−P_{ON}[i]/a[i]) (4)

In Formula 4, the heat flux Γ[i] is obtained by dividing the difference between second power P_{OFF}[i] and the first power P_{ON}[i], or a heat input J[i], by an area a[i] of the zone 20Z[i]. The second power P_{OFF}[i] is provided from the heater controller HC to the heater HT[i] when no plasma is generated in the chamber 10 and the zone 20Z[i] is controlled to be at the constant temperature Tc with the heater HT[i]. The second power P_{OFF}[i] is determined by the controller Cnt in step STp. Step STp may be performed at any selected time before step STc. The second power P_{OFF}[i] can also be determined using the same formula as the right side of Formula 3.

The difference between the second power P_{OFF}[i] and the first power P_{ON}[i] corresponds to the heat input J[i] from the plasma. The heat flux Γ[i] to the zone 20 Z[i] can be determined by dividing the heat input J[i] from the plasma to the zone 20Z[i] by the area a[i] of the zone 20Z[i]. The heat flux Γ[i] to the zone 20Z[i] reflects the density of plasma above the zone 20Z[i]. The method MT thus allows monitoring the conditions of plasma above the multiple zones 20Z.

As shown in FIG. 1, the method MT may further include step STd. In step STd, at least one of different applications is performed. These applications will now be described.

### First Application

In a first application, step STd includes determining a time-integrated value of the heat flux from plasma to each zone 20Z or a time-integrated value of the heat input from plasma to each zone 20Z. More specifically, the controller Cnt determines a time-integrated value A[i] of the heat flux Γ[i] from plasma to the zone 20Z[i] or a time-integrated value A[i] of the heat input J[i] from plasma to the zone 20Z[i] in step STd. Step STd further includes controlling plasma processing based on the time-integrated value A[i]. The plasma processing is controlled by the controller Cnt. In one or more embodiments of the present application, when the time-integrated value A[i] reaches a predetermined value while the plasma processing is being performed in step STa, different plasma processing is performed in the chamber 10.

In one example, the first application is performed for plasma etching of a multilayer film of the substrate W. When the time-integrated value A[i] reaches the predetermined value while the first layer of the multilayer film is undergoing plasma etching, the second layer of the multilayer film undergoes plasma etching. The process gas used for the plasma etching of the first layer differs from the process gas used for the plasma etching of the second layer. The first layer may be a silicon oxide film, and the second layer may be a silicon nitride film. The multilayer film of the substrate W may include multiple first layers and multiple second layers alternately stacked on one another.

### Second Application

In a second application, step STd includes determining the thickness of a plasma sheath above each zone 20Z based on the heat flux from plasma to the zone 20Z and a self-bias voltage in the substrate support 16. More specifically, a thickness T_{PS}[i] of the plasma sheath above the zone 20Z[i] is determined based on the heat flux Γ[i] and a self-bias voltage V_{dc}[i] in step STd. The thickness T_{PS}[i] is determined by the controller Cnt using Formula 5 below.

T_{PS}[i]=p×4.502×10³×(2V_{dc}[i])^{3/4}/(Tₑ^{1/4}×(nₑ[i])^{1/2}) (5)

In Formula 5, p is a predefined coefficient, Tₑ is a predetermined electron temperature, and nₑ[i] is an electron density determined using Formula 6 below. In Formulas 5 and 6, the self-bias voltage V_{dc}[i] is the above-described value V_{dcW} for the zone 20Z[i] below the substrate W. The self-bias voltage V_{dc}[i] is the above-described value V_{dcE} for the zone 20Z[i] below the edge ring ER.

nₑ[i]=q×r[i]/(V_{dc}[i])^{1/2} (6)

In Formula 6, q is a predefined coefficient.

In the second application, step STd further includes determining a direction in which ions from the plasma travel in a space above the multiple zones 20Z based on the thickness of the plasma sheath above the zones 20Z. More specifically, the direction in which the ions travel in a space above the zone 20Z[i], or an angle θ[i] between the direction in which the ions travel and the vertical direction, is determined by the controller Cnt using Formula 7 below.

θ[i]=x×arctan (|Tₚₛ[iₙ]−T_{PS}[i]/y) (7)

In Formula 7, x and y are predefined coefficients. A thickness T_{PS}[in] is the thickness of the plasma sheath above the zone 20Z[in] adjacent to and radially inward from the zone 20Z[i] among the multiple zones 20Z. In Formula 7, y may be the distance between the center of the zone 20Z[i] and the zone 20Z[i−1] on the same radius about the axis AX.

In the second application, step STd may include controlling an adjuster 70 (refer to FIG. 3) to correct the direction in which the ions travel to the edge of the substrate W to be the vertical direction. The adjuster 70 is controlled by the controller Cnt. The adjuster 70 may adjust a voltage to be applied to the edge ring ER to correct the direction in which the ions travel to be the vertical direction. In some embodiments, the adjuster 70 may change the position of the edge ring ER in the vertical direction to correct the direction in which the ions travel to be the vertical direction.

In step STd in the second application, a thickness T_{PS}[i_{OM}] of the sheath above a zone 20Z[i_{OM}] (first zone) in the outermost annular area and a thickness T_{PS}[i_{NB}] of the sheath above a zone 20Z[i_{NB}] (second zone) adjacent to and inward from the zone 20Z[i_{OM}] may be determined. In step STd, the controller Cnt may control the adjuster 70 to cause the thickness T_{PS} [i_{OM}] to be substantially the same as the thickness T_{PS} [i_{NB}]. The adjuster 70 may adjust a voltage to be applied to the edge ring ER to cause the thickness T_{PS}[i_{OM}] to be substantially the same as the thickness T_{PS}[i_{NB}] or may change the position of the edge ring ER in the vertical direction. More specifically, the position of the upper end of the sheath above the substrate W in the height direction and the position of the upper end of the sheath above the edge ring ER in the height direction may be determined. The position of the upper end of the sheath above the substrate W in the height direction is above the upper surface of the substrate support area in the height direction by the thickness of the substrate W and the thickness T_{PS} [i_{NB}]. The position of the upper end of the sheath above the edge ring ER in the height direction is above the upper surface of the edge ring support area in the height direction by the thickness of the edge ring ER and the thickness T_{PS} [i_{OM}]. Subsequently, the absolute value of the difference between the position of the upper end of the sheath above the substrate W in the height direction and the position of the upper end of the sheath above the edge ring ER in the height direction may be determined. When the absolute value exceeds a predetermined threshold, the adjuster 70 may adjust a voltage to be applied to the edge ring ER to cause the position of the upper end of the sheath above the substrate W in the height direction to be substantially the same as the position of the upper end of the sheath above the edge ring ER in the height direction, or may change the position of the edge ring ER in the vertical direction. The thickness T_{PS}[i_{NB}] may be calculated as the average of the thicknesses of sheath portions above the multiple zones 20Z[i_{NB}] adjacent to the outermost zone 20Z[i_{OM}] and defined in the circumferential direction. The thickness of the edge ring ER may be measured with a separate measurement device. In some embodiments, the thickness of the edge ring ER may be determined by the controller Cnt referring to the database and using the accumulated time of the plasma processing.

### Third Application

In a third application, step STd may reduce variations in the heat fluxes Γ to the zones 20Z determined in step STc. The variations in the heat fluxes Γ to the zones 20Z may be reduced through at least one of first to third processes. The first process includes individually adjusting current to be supplied from the power supply 50 to each electromagnet 30. The second process includes adjusting the distribution of the flow rate of the process gas in the radial direction of the substrate W using the flow splitter 24d. The third process includes individually adjusting the temperatures of the zones 20Z using the multiple heaters HT. In the third application, the controller Cnt controls the power supply 50, the flow splitter 24d, and the heater controller HC. The third application achieves the uniform density distribution of plasma. Instead of or in addition to this, the uniformity of the plasma processing (e.g., plasma etching) across the processing plane of the substrate W is improved in the third application.

### Fourth Application

In a fourth application, step STd includes monitoring the change in the heat flux Γ to each zone 20Z determined in step STc over time. Step STd including monitoring the change in the heat flux Γ over time can be performed by the controller Cnt.

In one example of step STd in the fourth application, the daily change in the heat flux Γ to each zone 20Z over time determined in step STc can be monitored to determine whether the plasma processing apparatus 1 operates stably.

In another example of step STd in the fourth application, seasoning may be started after replacement of a component in the chamber 10, and the seasoning may end when the heat flux Γ to each zone 20Z satisfies the condition for determining the heat flux Γ to be stable. When the chamber 10 is vented to the atmosphere and the impedance of the chamber 10 changes from the state before the chamber 10 is vented, ion energy entering the substrate on the substrate support 16 also changes. The Change in the impedance of the chamber 10 may occur when, after the chamber 10 is opened for, for example, replacement of a component, water accumulates on the surface of the chamber 10, when a replacement component is placed in the chamber 10, or when the deposits on the components in the chamber 10, on the inner surface of the chamber 10, or on both are exposed to the atmosphere and their compositions change. Seasoning after evacuating the chamber 10 stabilizes the impedance of the chamber 10 to a predetermined value, and also stabilizes ion energy entering the substrate to a predetermined value. Thus, when the heat flux Γ reaches a predetermined value as a target value for the seasoning, the seasoning may end. Thus, the heat flux Γ to at least one of the multiple zones 20Z may be monitored, or the heat fluxes Γ to two or more zones 20Z or to all the zones 20Z may be monitored. When the heat fluxes Γ to two or more zones 20Z or to all the zones 20Z are monitored, the seasoning may end when the heat fluxes Γ are stabilized. In some embodiments, the seasoning may end when the heat fluxes Γ to one or more selected zones of the multiple zones 20Z are stabilized.

In still another example of step STd in the fourth application, a heater output to each zone 20Z may be monitored over time to detect abnormal clamping of the substrate W by the ESC 20. Under abnormal clamping of the substrate W by the ESC 20, the ESC 20 may not clamp the substrate W normally or the ESC 20 may have a smaller clamping force. Under abnormal clamping of the substrate W by the ESC 20, heat from the plasma is not normally transferred to the ESC 20 through the substrate W. Thus, under abnormal clamping of the substrate W by the ESC 20, the heater output (power output from the heater controller) during plasma processing is higher than the heater output when the substrate W is normally clamped by the ESC 20. Monitoring the heater output over time during plasma processing of one substrate W, monitoring the heater output over time for each cycle of plasma processing of substrates W, or monitoring both can be used to identify the timing at which an abnormal clamping of the substrate W occurs, and thus the substrate W that has undergone plasma processing under abnormal clamping is identified. In this example, the heater output to at least one of the zones 20Z may be monitored, or the heater output to two or more zones 20Z or to all the zones 20Z may be monitored. Monitoring the heater output to the zones 20Z can also be used to identify an area in which abnormal clamping occurs in the ESC 20. In addition to the detection of the abnormal clamping of the substrate W by the ESC 20, abnormal clamping of the edge ring ER by the ESC 20 is also detectable.

In still another example of step STd in the fourth application, the heat flux Γ to each zone 20Z over time can be monitored to detect the end point of the plasma processing performed on the substrate W.

### Fifth Application

In a fifth application, step STd includes monitoring the electron density nₑ[i] described above. Step STd including monitoring the electron density nₑ[i] may be performed by the controller Cnt. The electron density nₑ[i] may be monitored to detect the wear of a component, for example, the upper electrode 22, in the chamber 10.

### Sixth Application

In a sixth application, step STd includes monitoring power provided from the heater controller HC to the heater HT in the zone 20Z below the edge ring ER. Step STd including monitoring power may be performed by the controller Cnt. As the edge ring ER has a smaller thickness, the power provided from the heater controller HC to the heater HT in the zone 20Z below the edge ring ER decreases. Thus, the decrease in the thickness of the edge ring ER can be detected by monitoring the power provided from the heater controller HC to the heater HT in the zone 20Z below the edge ring ER.

Although the exemplary embodiments have been described above, the embodiments are not restrictive, and various additions, omissions, substitutions, and changes may be made. The components in the different exemplary embodiments may be combined to form another exemplary embodiment.

In another embodiment, the plasma processing apparatus may be of another type, such as an inductively coupled plasma processing apparatus, an electron cyclotron resonance (ECR) plasma processing apparatus, or a plasma processing apparatus that generates plasma using surface waves such as microwaves.

The exemplary embodiments according to the disclosure have been described by way of example, and various changes may be made without departing from the scope and spirit of the disclosure. The exemplary embodiments described above are thus not restrictive, and the true scope and spirit of the disclosure are defined by the appended claims.

### REFERENCE SIGNS LIST

1 Plasma processing apparatus
10 Chamber
16 Substrate support
20Z Zone
HT Heater
HC Heater controller
Cnt Controller

1. A monitoring method, comprising:
determining first power provided to heaters, each heater being located in a corresponding zone of a plurality of zones in a substrate support in a plasma processing apparatus, the substrate support being located in a chamber in the plasma processing apparatus, the first power being provided when plasma is generated in the chamber and each of the plurality of zones is controlled to be at a constant temperature by the corresponding heater in the zone; and
determining a heat flux from the plasma to each of the plurality of zones by dividing a difference between second power and the first power provided to the corresponding heater in the zone by an area of the zone,
wherein for each zone, the second power to the corresponding heater in the zone is provided when no plasma is generated in the chamber and the zone is controlled to be at the constant temperature with the corresponding heater in the zone.

2. The monitoring method according to claim 1, further comprising:
determining a time-integrated value of the heat flux from the plasma to each of the plurality of zones or a time-integrated value of a heat input from the plasma to each of the plurality of zones; and
controlling plasma processing with the plasma based on the time-integrated value of the heat flux from the plasma to each of the plurality of zones or based on the time-integrated value of the heat input from the plasma to each of the plurality of zones.

3. The monitoring method according to claim 2, wherein
controlling the plasma processing includes performing different plasma processing in the chamber when the time-integrated value of the heat flux or the time-integrated value of the heat input reaches a predetermined value.

4. The monitoring method according to claim 1, further comprising:
determining a thickness of a plasma sheath above each of the plurality of zones based on the heat flux from the plasma to each zone and a self-bias voltage in the substrate support.

5. The monitoring method according to claim 4, wherein
the plurality of zones include at least one first zone below an edge ring and at least one second zone adjacent to and inward from the at least one first zone, and
determining the thickness of the plasma sheath includes determining the thickness of the plasma sheath above the edge ring and the thickness of the plasma sheath above the at least one second zone.

6. The monitoring method according to claim 4, further comprising:
determining, based on a thickness of the plasma sheath above at least one first zone located below an edge ring among the plurality of zones, a position of an upper end of the plasma sheath above the edge ring in a height direction; and
determining, based on a thickness of the plasma sheath above at least one second zone located below a substrate among the plurality of zones, a position of the upper end of the plasma sheath above the substrate in the height direction.

7. The monitoring method according to claim 5, further comprising:
controlling an adjuster to cause a thickness of the plasma sheath above the at least one first zone to be substantially same as the thickness of the plasma sheath above the at least one second zone,
wherein, in controlling the adjuster, the adjuster is controlled to adjust a voltage applied to the edge ring or to change a position of the edge ring in a vertical direction.

8. The monitoring method according to claim 6, further comprising:
controlling an adjuster to cause a position of the upper end of the plasma sheath above the at least one first zone in the height direction to be substantially same as a position of the upper end of the plasma sheath above the at least one second zone in the height direction,
wherein, in controlling the adjuster, the adjuster is controlled to adjust a voltage applied to the edge ring or to change a position of the edge ring in a vertical direction.

9. The monitoring method according to claim 4, further comprising:
determining a direction in which ions from the plasma travel in a space above each of the plurality of zones based on the thickness of the plasma sheath above each zone.

10. A plasma processing apparatus, comprising:
a chamber;
a plasma generator configured to generate plasma in the chamber;
a substrate support in the chamber, the substrate support including heaters each located in a corresponding zone of a plurality of zones in the substrate support;
a heater controller configured to provide power to the heaters in the plurality of zones; and
a controller configured to:
determine first power provided from the heater controller to the corresponding heater in each of the plurality of zones when the plasma is generated in the chamber and each of the plurality of zones is controlled to be at a constant temperature with the corresponding heater in the zone, and
determine a heat flux from the plasma to each of the plurality of zones by dividing a difference between second power and the first power provided to the corresponding heater in the zone by an area of the zone,
wherein for each zone, the second power to the corresponding heater is provided when no plasma is generated in the chamber and the zone is controlled to be at the constant temperature with the corresponding heater in the zone.

11. The plasma processing apparatus according to claim 10, wherein
the controller further determines a time-integrated value of the heat flux from the plasma to each of the plurality of zones or a time-integrated value of a heat input from the plasma to each of the plurality of zones, and
the controller further controls plasma processing with the plasma based on the time-integrated value of the heat flux from the plasma to each of the plurality of zones or the time-integrated value of the heat input from the plasma to each of the plurality of zones.

12. The plasma processing apparatus according to claim 11, wherein
the controller further performs different plasma processing in the chamber when the time-integrated value of the heat flux or the time-integrated value of the heat input reaches a predetermined value.

13. The plasma processing apparatus according to claim 10, wherein
the controller further determines a thickness of a plasma sheath above each of the plurality of zones based on the heat flux from the plasma to the zone and a self-bias voltage in the substrate support.

14. The plasma processing apparatus according to claim 13, wherein
the plurality of zones include at least one first zone below an edge ring and at least one second zone adjacent to and inward from the at least one first zone, and
the controller determines, as the thickness of the plasma sheath above each of the plurality of zones, a thickness of the plasma sheath above the edge ring and a thickness of the plasma sheath above the at least one second zone.

15. The plasma processing apparatus according to claim 13, wherein
the plurality of zones include at least one first zone below an edge ring and at least one second zone below a substrate,
the controller further determines, based on a thickness of the plasma sheath above the at least one first zone, a position of an upper end of the plasma sheath above the edge ring in a height direction, and
the controller further determines, based on a thickness of the plasma sheath above the at least one second zone, a position of the upper end of the plasma sheath above the substrate in the height direction.

16. The plasma processing apparatus according to claim 14, wherein
the controller further controls an adjuster to cause a thickness of the plasma sheath above the at least one first zone to be substantially same as the thickness of the plasma sheath above the at least one second zone, and
the adjuster is controlled by the controller to adjust a voltage applied to the edge ring or to change a position of the edge ring in a vertical direction.

17. The plasma processing apparatus according to claim 15, wherein
the controller further controls the adjuster to cause a position of the upper end of the plasma sheath above the at least one first zone in the height direction to be substantially same as a position of the upper end of the plasma sheath above the at least one second zone in the height direction, and
the adjuster is controlled by the controller to adjust a voltage applied to the edge ring or to change a position of the edge ring in a vertical direction.

18. The plasma processing apparatus according to claim 13, wherein
the controller further determines a direction in which ions from the plasma travel in a space above each of the plurality of zones based on the thickness of the plasma sheath above each zone.

19. The plasma processing apparatus according to claim 13, further comprising:
a plurality of electromagnets arranged on in in a ceiling of the chamber,
wherein the controller individually adjusts current supplied to each of the electromagnets and individually adjusts temperatures of the plurality of zones using the plurality of heaters to cause a uniform density distribution of plasma during plasma processing.

20. The monitoring method according to claim 6, wherein the plasma processing apparatus further includes a plurality of electromagnets arranged on in in a ceiling of the chamber, and
the method further comprises individually adjusting current supplied to each of the electromagnets and individually adjusting temperatures of the plurality of zones using the plurality of heaters, during plasma processing to cause a uniform density distribution of plasma.
